(19) United States
(12) Patent Application Publication
(10) Pub. No.: US 2026/0082667 A1
(43) Pub. Date: Mar. 19, 2026

(54) Deep Contact with Nanosheet Interface

(71) Applicant: Applied Materials, Inc., Santa Clara, CA (US)

(72) Inventor: Nicolas Louis BREIL, San Jose, CA (US)

(21) Appl. No.: 18/887,320

(22) Filed: Sep. 17, 2024

(51) Int. Cl. H01L 29/49; H01L 21/285; H01L 29/06; H01L 29/16; H01L 29/417; H01L 29/423; H01L 29/66; H01L 29/775; H01L 29/786

(52) U.S. Cl. CPC H10D 64/663; H10D 30/6729; H10D 64/0113; H10D 30/014; H10D 30/43; H10D 30/6735; H10D 30/6757; H10D 62/121; H10D 62/83

(57) ABSTRACT

A method for forming a contact for a source-drain of a gate all around structure incorporates exposing at least a portion of a nanosheet during formation of the contact. A method may include removing a source-drain material to form an exposed portion of a nanosheet material of at least one nanosheet, forming epitaxial contact layers on the source-drain material and the exposed portion of the nanosheet material, forming a silicide contact layer on at least the epitaxial contact layers, and forming a contact with a metal material on the silicide contact layer. In some embodiments, an exposed portion of the nanosheet material comprises an entire end of at least one nanosheet alone or in conjunction with at least a portion of another nanosheet or in conjunction with an entire end of at least one other nanosheet.

### FIELD

Embodiments of the present principles generally relate to semiconductor processing of semiconductor substrates.

### BACKGROUND

Horizontal gate-all-around (hGAA) stacked nanosheet structures are likely to be the basis of the next evolution of transistors. The stacked nanosheets have a source-drain that engages with each nanosheet of the stacked nanosheets. A metal contact then engages with the source-drain via a silicide contact interface layer. Improvements of the contact area between the metal contact and the source-drain have been made to increase the contact area and lower contact resistance. However, the inventor has observed that devices using such a nanosheet structure may be performance-constrained by the metal contact material having a source-drain material positioned between the contact material and the nanosheet material.

Accordingly, the inventor has provided methods and architectures for improving the interfaces between the contact, the source-drain, and the nanosheet structure.

### SUMMARY

Methods for altering the interfaces between a contact, a source-drain, and a nanosheet structure are provided herein.

In some embodiments, a method for forming a contact for a nanosheet structure may comprise removing a source-drain material to form an exposed portion of a nanosheet material of at least one nanosheet, forming epitaxial contact layers on the source-drain material and the exposed portion of the nanosheet material, forming a silicide contact layer on at least the epitaxial contact layers, and forming a contact with a metal material on the silicide contact layer.

In some embodiments, the method may further include an exposed portion of the nanosheet material that comprises an entire end of the at least one nanosheet, an exposed portion of the nanosheet material that comprises an entire end of the at least one nanosheet and at least a portion of another nanosheet, an exposed portion of the nanosheet material that comprises an entire end of one of the at least one nanosheet and an entire end of another one of the at least one nanosheet, forming epitaxial contact layers using a deposition process that is selective of silicon over other materials, removing the source-drain material using a plasma-based process that uses hydrogen and chlorine, hydrogen and chlorine with argon, hydrogen and chlorine with helium, or hydrogen and chlorine with argon and helium, a source-drain material that is silicon germanium and where removing the source-drain material forms a V-shape in the source-drain material at a (111) crystal plane of the source-drain material, epitaxial contact layers that have a higher germanium content than the source-drain material, epitaxial contact layers that have a higher boron content than the source-drain material, and/or epitaxial contact layers that have a thickness of approximately 4 nm to approximately 10 nm.

In some embodiments, a contact of a nanosheet structure may comprise a stack of two or more nanosheets, a source-drain in direct contact with at least one of the two or more nanosheets where the source-drain is formed of a source-drain material, a first epitaxial contact layer on the source-drain, and at least one second epitaxial contact layer in direct contact with at least a portion of one of the two or more nanosheets.

In some embodiments, the contact may further comprise a silicide layer on the first epitaxial contact layer and the at least one second epitaxial contact layer and a contact material on the silicide layer, a silicide layer that is a conformal layer that covers the first epitaxial contact layer and the at least one second epitaxial contact layer, two or more nanosheets that are formed of silicon germanium doped with boron, a first epitaxial contact layer and at least one second epitaxial contact layer that have a higher germanium content than the source-drain material, a first epitaxial contact layer and at least one second epitaxial contact layer that have a higher boron content than the source-drain material, an uppermost surface of a source-drain that forms a V-shape in the source-drain material at a (111) crystal plane of the source-drain material or an uppermost surface of the source-drain that forms a U-shape in the source-drain material, and/or a V-shape having an angle of approximately 65 degrees to approximately 80 degrees.

In some embodiments, a non-transitory, computer readable medium having instructions stored thereon that, when executed, cause a method for forming a contact for a nanosheet structure to be performed, the method may comprise removing a source-drain material to expose at least a portion of at least one nanosheet where the at least one nanosheet is formed of a nanosheet material, forming epitaxial contact layers on the source-drain material and any exposed portions of the nanosheet material, forming a silicide contact layer on at least the epitaxial contact layers, and forming a contact with a metal material on the silicide contact layer.

In some embodiments, the method of the non-transitory, computer readable medium may further include an exposed portion of the nanosheet material that comprises an entire end of the at least one nanosheet, an entire end of the at least one nanosheet and at least a portion of another nanosheet, or an entire end of one of the at least one nanosheet and an entire end of another one of the at least one nanosheet.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a method of forming a contact for a nanosheet structure in accordance with some embodiments of the present principles.

FIG. 2 depicts a cross-sectional view of a gate-all-around (GAA) device with a nanosheet structure in accordance with some embodiments of the present principles.

FIG. 3 depicts a cross-sectional view of various V-shaped etch stop lines for a source-drain in accordance with some embodiments of the present principles.

FIG. 4 depicts a cross-sectional view of an example with a V-shaped etch stop line exposing a first edge of a first nanosheet in accordance with some embodiments of the present principles.

FIG. 5 depicts cross-sectional views of epitaxial contact layers formed on a source-drain and a nanosheet edge in accordance with some embodiments of the present principles.

FIG. 6 depicts a cross-sectional view of a silicide contact layer in accordance with some embodiments of the present principles.

FIG. 7 depicts a cross-sectional view of a contact formed on a V-shaped source-drain surface in accordance with some embodiments of the present principles.

FIG. 8 depicts a cross-sectional view of various U-shaped etch stop lines for a source-drain in accordance with some embodiments of the present principles.

FIG. 9 depicts a cross-sectional view of an example with a U-shaped etch stop line exposing a first edge of a first nanosheet in accordance with some embodiments of the present principles.

FIG. 10 depicts a cross-sectional view of a contact formed on a U-shaped source-drain surface in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods and architectures provide tunable interfaces between a contact, a source-drain, and individual nanosheets of a nanosheet structure to alter the performance of a nanosheet stack-based device (e.g., horizontal gate-all-around (hGAA) transistor, etc.). The present techniques facilitate in lowering contact resistance by adjusting the materials and the proximity of the contact and nanosheet interfaces. By allowing a more direct interface between the contact and one or more nanosheets, increased carrier injection becomes possible, increasing the performance of the nanosheet-based device. In addition, the present methods allow for adjustments of the architecture on an as needed basis, substantially increasing the flexibility of the process without introducing new processes/equipment or all or nothing processes that are found in traditional nanosheet stack manufacturing.

Traditionally, each nanosheet of a nanosheet stack interfaces with a single source-drain. Contact performance improvements for such designs have centered around increasing the interface area between the metal contact material and the source-drain material. Even with such improvements, the contact resistance may still be a substantial performance block. The inventor has found that by deep etching the source-drain material, the metal contact material can be brought into closer proximity with one or more of the nanosheets in a nanosheet stack, substantially improving the overall contact resistance. In some embodiments, by using a cavity etch process that produces a V-shaped upper surface of the source-drain material, the interface area with the source-drain is increased while also improving carrier injection to one or more nanosheets. For example, the cavity etch process can be allowed to continue to etch the source-drain material past one or more nanosheets to expose at least a portion of the one or more nanosheets. An epitaxial contact layer can then be formed on the V-shaped upper surface of the source-drain material and the exposed portions of nanosheet material followed by a silicide contact layer and deposition of the metal contact material. By exposing portions of the one or more nanosheets, the metal contact material interfaces with the nanosheet material only through the epitaxial contact layer and the silicide contact layer and not through the source-drain material. The reduced interface layers between the metal contact material and the nanosheet material allows for increased carrier injection into the exposed portions of the one or more nanosheets, decreasing the overall contact resistance. Adjustments can be made on the etch depth and the amount of nanosheet exposure on an as needed basis to finely tune the architecture for each design.

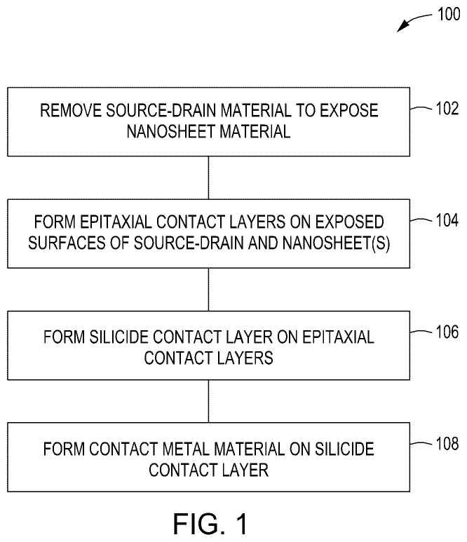

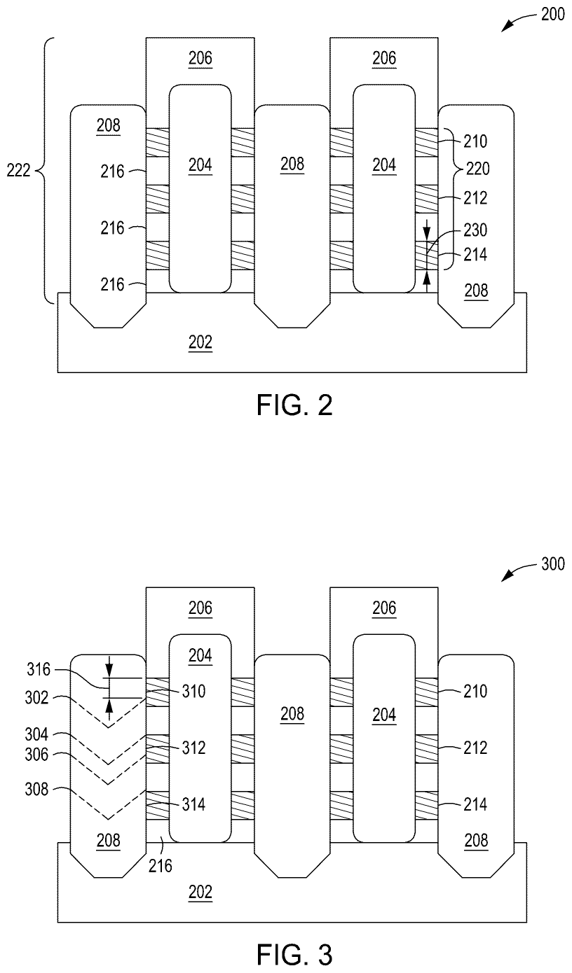

FIG. 1 is a method 100 for forming a contact for a nanosheet structure. An example of a nanosheet structure 220 in a GAA device 222 is depicted in a view 200 of FIG. 2. The present methods are not limited by the type of device in FIG. 2. The GAA device 222 of FIG. 2 is used as the example in the following scenarios for the sake of brevity. In the example of FIG. 2, the GAA device 222 has a gate 204 surrounding the nanosheet structure 220 with a gate cap 206 and source-drains 208 (which may be referred to as source-drain regions) on each side of the nanosheet structure 220, all of which are formed on a substrate 202. The nanosheet structure 220, in the example, has a first nanosheet 210, a second nanosheet 212, and a third nanosheet 214 which may be formed, in some embodiments, of a semiconductor material such as an epitaxially grown silicon germanium (SiₓGe₁₋ₓ) material. The number of nanosheets in a stack may be more or less than the example of FIG. 2. In some embodiments, X may be from approximately 0.85 to approximately 0.95. In some embodiments, the SiGe may be further doped with a dopant such as boron and the like. In some embodiments, the nanosheets may have a thickness 230 of approximately 5 nm to approximately 10 nm. In some embodiments, the thickness may be approximately 6 nm. The nanosheets may be separated by inner spacers 216 composed of a dielectric material. For the sake of brevity, the formation of the GAA device 222, as depicted in the view 200 of FIG. 2, is not discussed and is used as a starting point for the present methods. In other words, the epitaxial growth of the source-drain material of the source-drain 208 has been completed. In some embodiments, the source-drain material may be SiGe with a boron dopant and the like.

In block 102, a portion of the source-drain material of the source-drain 208 is removed to expose a nanosheet material of the nanosheet structure 220. In some embodiments, the source-drain material may be SiGe with boron and have a (111) crystal plane that allows the source-drain material to be removed down to the (111) crystal plane, forming a V-shape in the top of the source-drain 208. The amount of source-drain material removed is tunable using the present methods and can vary depending upon a desired application and performance (low resistance, high current, etc.). In some embodiments, the source-drain material may be removed to expose a first edge 310 of the first nanosheet 210 with an exposed edge height 316 as depicted in a view 300 of FIG. 3. The exposed edge height 316 of the first edge 310 of the first nanosheet 210 is tunable. In the example, the V-shaped dashed line 302 indicates a stop line for etching of the source-drain material that yields the exposed edge height 316 of the first edge 310 of the first nanosheet 210.

In some embodiments, the source-drain material may be etched down to the V-shaped dashed line 304 to fully expose the first edge 310 of the first nanosheet 210. In some embodiments, the source-drain material may be etched down to the V-shaped dashed line 306 to fully expose the first edge 310 of the first nanosheet 210 and to partially expose the second edge 312 of the second nanosheet 212. In some embodiments, the source-drain material may be etched down to the V-shaped dashed line 308 to fully expose the first edge 310 and to fully expose the second edge 312. The etch stop line does not have to be V-shaped and can be planar and/or curved (U-shaped, etc.) and the like. During design of a device, the amount of edge exposure may be a tradeoff between low resistance (metal contact nearer exposed edges) and current carrying capability (current crowding at the exposed edges). The example etch stop lines of the view 300 are not meant to be limiting as the present methods are tunable to any conceivable etch stop line such as, for example, from partial exposure of the third edge 314 of the third nanosheet 214 to full exposure of the third edge 314 of the third nanosheet 214 and anywhere in between the first nanosheet 210 and the third nanosheet 214 and the like.

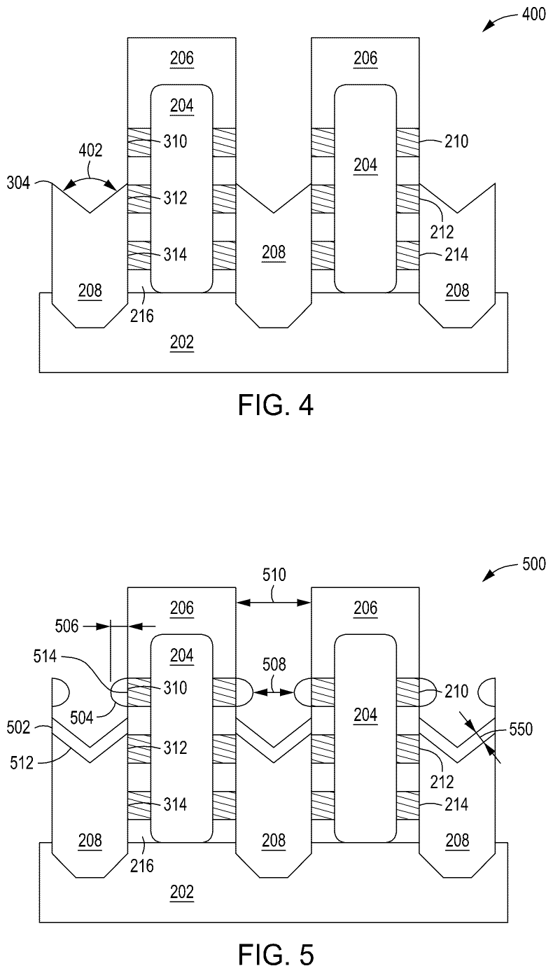

In the example, in a view 400 of FIG. 4, the source-drain material of the source-drain 208 has been removed down to a surface that was represented by the V-shaped dashed line 304 which totally exposes the first edge 310 of the first nanosheet 210. In some embodiments that utilize the V-shaped dashed line 304 as an etch stop point, lower contact resistance is obtained by the metal contact having direct access to the first nanosheet 210 and closer access to the second nanosheet 212. In the example, the V-shaped dashed line 304 indicates a (111) crystal plane within the SiₓGe₁₋ₓ crystal structure of the epitaxially grown source-drain material. However, the etching or removal of the source-drain material is not required to stop on the (111) crystal plane and, thus, the present methods may be adjusted to yield any type of surface topology on the exposed surface of the source-drain 208. The angle 402 of the V-shape may also be adjusted as desired. In some embodiments, a 72 degree angle may be used with the (111) crystal plane to maximize the contact area (exposed surface) of the source-drain 208. In some embodiments, an approximately 65 degree to approximately 80 degree angle may be used for the contact area.

The duration and/or the amount of RF bias can be used to control the etch rate, direction, and etch depth of a removal process. In some embodiments, etching of the SiGe of the source-drain 208 may be performed using a plasma-based etching process using hydrogen and chlorine with or without an RF bias. In some embodiments, the hydrogen and chlorine may be diluted using argon and/or helium. The hydrogen and chlorine etching process saturates on the (111) plane of the SiGe crystal structure. The germanium chloride stays on the (111) plane and passivates the (111) plane against the germanium hydrogen halting the etching process on the (111) plane of the SiGe material of the source-drain 208. The inventor unexpectedly discovered that during the etching process, the SiGe of the first nanosheet 210 was exposed but was minimally affected by the etching process. The extension region under the gate cap 206 effectively halts the etching due to the much slower etch rate of the materials in the extension region compared to the source-drain material, allowing removal of the source-drain material with little or no etching of the extension region materials. The discovery allows the present methods to be used to tune the nanosheet exposure to any level needed by a design as discussed above (e.g., more exposure—lower resistance but more current crowding, less exposure—higher resistance but less current crowding, etc.).

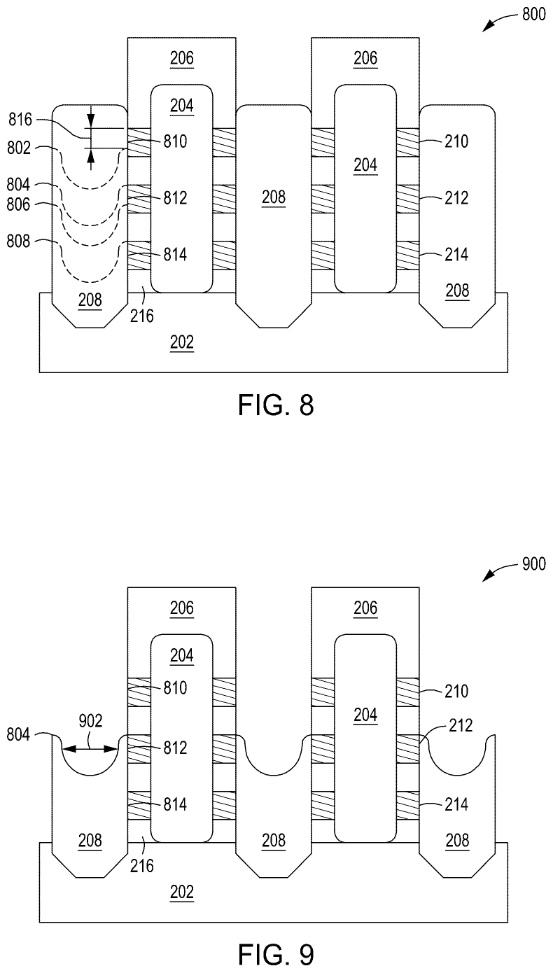

In an alternative example, a portion of the source-drain material of the source-drain 208 is removed to expose a nanosheet material of the nanosheet structure 220, forming a U-shape in the top of the source-drain 208. The amount of source-drain material removed is tunable using the present methods and can vary depending upon a desired application and performance (low resistance, high current, etc.). In some embodiments, the source-drain material may be removed to expose a first edge 810 of the first nanosheet 210 with an exposed edge height 816 as depicted in a view 800 of FIG. 8. The exposed edge height 816 of the first edge 810 of the first nanosheet 210 is tunable. In the example, the U-shaped dashed line 802 indicates a stop line for etching of the source-drain material that yields the exposed edge height 816 of the first edge 810 of the first nanosheet 210.

In some embodiments, the source-drain material may be etched down to the U-shaped dashed line 804 to fully expose the first edge 810 of the first nanosheet 210. In some embodiments, the source-drain material may be etched down to the U-shaped dashed line 806 to fully expose the first edge 810 of the first nanosheet 210 and to partially expose the second edge 812 of the second nanosheet 212. In some embodiments, the source-drain material may be etched down to the U-shaped dashed line 808 to fully expose the first edge 810 and to fully expose the second edge 812. The etch stop line does not have to be U-shaped and can be planar and/or curved and the like to maintain (planar) or increase the surface contact area (V-shaped, U-shaped, etc.). During design of a device, the amount of edge exposure may be a tradeoff between low resistance (metal contact nearer exposed edges) and current carrying capability (current crowding at the exposed edges). The example etch stop lines of the view 800 are not meant to be limiting as the present methods are tunable to any conceivable etch stop line such as, for example, from partial exposure of the third edge 814 of the third nanosheet 214 to full exposure of the third edge 814 of the third nanosheet 214 and anywhere in between the first nanosheet 210 and the third nanosheet 214 and the like.

In the example, in a view 900 of FIG. 9, the source-drain material of the source-drain 208 has been removed down to a surface that was represented by the U-shaped dashed line 804 which totally exposes the first edge 810 of the first nanosheet 210. In some embodiments that utilize the U-shaped dashed line 804 as an etch stop point, lower contact resistance is obtained by the metal contact having direct access to the first nanosheet 210 and closer access to the second nanosheet 212. The present methods may be adjusted to yield any type of surface topology on the exposed surface of the source-drain 208 and are not limited to the V-shaped and U-shaped examples. The width 902 of the U-shape may also be adjusted as desired.

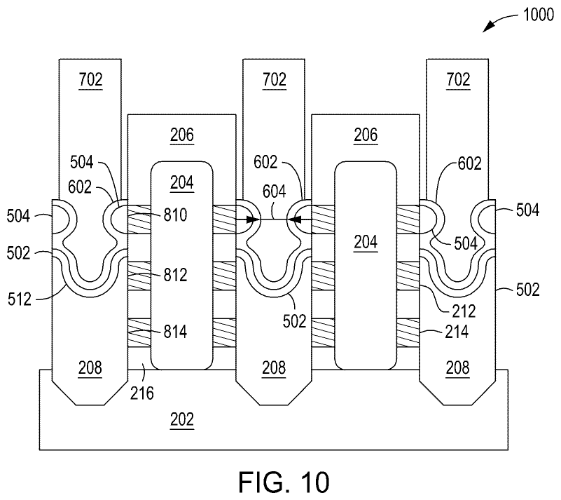

In block 104, epitaxial contact layers are formed on the exposed surfaces of the source-drain and the nanosheet(s) as depicted in a view 500 of FIG. 5 for V-shaped source drain surfaces (see also view 1000 of FIG. 10 for U-shaped source-drain surfaces). In some embodiments, the epitaxial contact layers are formed of SiₓGe₁₋ₓ with boron dopants. By using a high concentration of germanium (e.g., where 1−X is approximately 20% to 30% or more), the epitaxial contact layers provide good contact with low contact resistivity. In some embodiments, the epitaxial contact layers have a higher germanium and boron dopant content (and activation) than that of the source-drain material. In the examples, a first epitaxial contact layer 502 is formed on the source-drain on the exposed source-drain surface 512, and a second epitaxial contact layer 504 is formed on the exposed first nanosheet surface 514. The formation of the first epitaxial contact layer 502 and the second epitaxial contact layer 504 may be accomplished using a single process or individual processes tuned for epitaxial growth on specific underlying materials of the first epitaxial contact layer 502 and the second epitaxial contact layer 504, respectively.

In the examples, the second epitaxial contact layer 504 is selectively formed on the exposed first nanosheet surface 514, as the germanium content of the SiₓGe₁₋ₓ plus boron material of the first nanosheet 210 is low (e.g., where 1−X is approximately 5% to 10% germanium, etc.). The available width 510 for constructing the contact to the source-drain and nanosheets is limited. The width 508 between the second epitaxial contact layers 504 cannot be so small as to not allow gap filling with the contact material during subsequent processes. The width 508 is regulated by the thickness 506 of the second epitaxial contact layer 504 on the edge of any exposed nanosheets (e.g., first edge 310 of first nanosheet 210, etc.). As an example, the available width 510 may be approximately 25 nm, the thickness 506 of the second epitaxial contact layer 504 may be approximately 4 nm to approximately 10 nm, which yields a 5 nm to 17 nm width for the width 508. In some cases, the thickness 506 may be kept large to reduce current crowding at the edge of the nanosheet and to have better carrier injection by the contact, but with a tradeoff of a large thickness reducing the metal contact material at that junction. Relative thicknesses between the two epitaxial contact layers on the first nanosheet 210 and the source-drain 208 are not depicted to scale so that greater detail can be shown for the second epitaxial contact layer 504 of the first nanosheet 210. In some embodiments, the thickness 550 of the first epitaxial contact layer 502 will be similar to that of the thickness 506 of the second epitaxial contact layer 504.

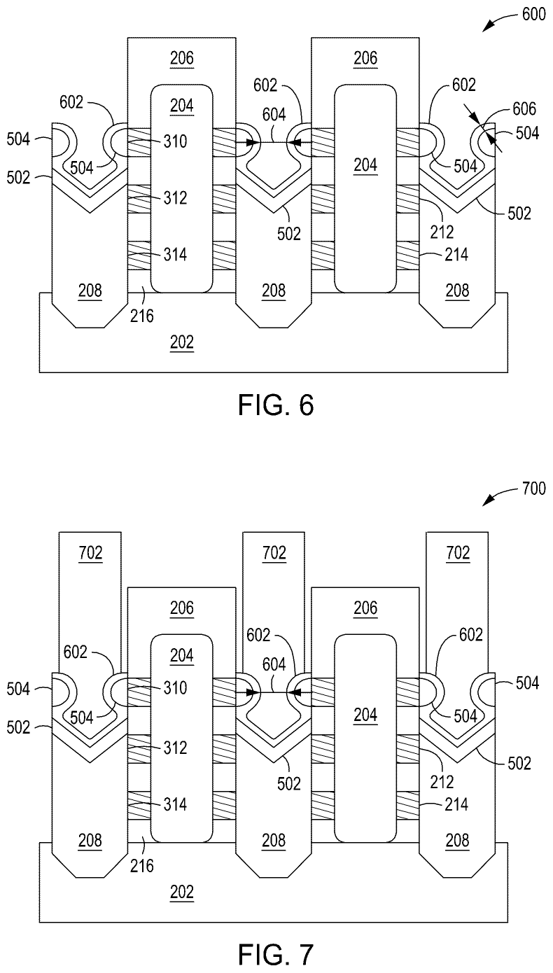

In block 106, a silicide contact layer 602 is formed on the epitaxial contact layers as depicted in a view 600 of FIG. 6 for V-shaped source drain surfaces (see also view 1000 of FIG. 10 for U-shaped source-drain surfaces). The silicide contact layer 602 is a conformal layer on at least the first epitaxial contact layer 502 and the second epitaxial contact layer 504. In some embodiments, the silicide contact layer 602 may be deposited by a physical vapor deposition (PVD), an atomic layer deposition (ALD), and/or a chemical vapor deposition (CVD) conformal deposition process. In some embodiments, the silicide contact layer 602 may be formed of silicide based on tantalum, titanium, ruthenium, molybdenum, nickel, platinum, zirconium, hafnium, ytterbium, erbium, yttrium, and/or silicon and the like. The thickness 606 of the silicide contact layer 602 may be from greater than zero to approximately 1 nm. The thickness 606 of the silicide contact layer 602 has a minimal impact on the available contact width 604 as compared to impact after forming the epitaxial contact layers (width 508 vs available width 510). In block 108, in some embodiments, contact metal material 702 is formed on the silicide contact layer 602 as depicted in a view 700 of FIG. 7 based on a V-shaped etching of the top surface of the source-drain 208. In some embodiments, contact metal material 702 is formed on the silicide contact layer 602 as depicted in a view 1000 of FIG. 10 based on a U-shaped etching of the top surface of the source-drain 208. In some embodiments, the contact metal material 702 may be formed by a gapfill process and the like. Overall, the present methods and architectures produce a lower resistance contact for nanosheet structures. The highly tunable techniques allow for performance tweaking such as increased carrier injection (injection efficiency) at or nearer the nanosheets and adjusting of current crowding conditions at specific points of the extension region. The source-drain profile can also be adjusted as desired from different depths to different surface profiles of V-shaped surfaces to flat surfaces to any shape in between. The present techniques can also be incorporated into manufacturing processes using existing process equipment.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for forming a contact for a nanosheet structure, comprising:
removing a source-drain material to form an exposed portion of a nanosheet material of at least one nanosheet;
forming epitaxial contact layers on the source-drain material and the exposed portion of the nanosheet material;
forming a silicide contact layer on at least the epitaxial contact layers; and
forming a contact with a metal material on the silicide contact layer.

2. The method of claim 1, wherein the exposed portion of the nanosheet material comprises an entire end of the at least one nanosheet.

3. The method of claim 1, wherein the exposed portion of the nanosheet material comprises an entire end of the at least one nanosheet and at least a portion of another nanosheet.

4. The method of claim 1, wherein the exposed portion of the nanosheet material comprises an entire end of one of the at least one nanosheet and an entire end of another one of the at least one nanosheet.

5. The method of claim 1, wherein forming epitaxial contact layers uses a deposition process that is selective of silicon over other materials.

6. The method of claim 1, wherein removing the source-drain material comprises a plasma-based process that uses hydrogen and chlorine, hydrogen and chlorine with argon, hydrogen and chlorine with helium, or hydrogen and chlorine with argon and helium.

7. The method of claim 1, wherein the source-drain material is silicon germanium and wherein removing the source-drain material forms a V-shape in the source-drain material at a (111) crystal plane of the source-drain material.

8. The method of claim 1, wherein the epitaxial contact layers have a higher germanium content than the source-drain material.

9. The method of claim 1, wherein the epitaxial contact layers have a higher boron content than the source-drain material.

10. The method of claim 1, wherein the epitaxial contact layers have a thickness of approximately 4 nm to approximately 10 nm.

11. A contact of a nanosheet structure comprising:
a stack of two or more nanosheets;
a source-drain in direct contact with at least one of the two or more nanosheets, wherein the source-drain is formed of a source-drain material;
a first epitaxial contact layer on the source-drain; and
at least one second epitaxial contact layer in direct contact with at least a portion of one of the two or more nanosheets.

12. The contact of the nanosheet structure of claim 11, further comprising:
a silicide layer on the first epitaxial contact layer and the at least one second epitaxial contact layer; and
a contact material on the silicide layer.

13. The contact of the nanosheet structure of claim 12, wherein the silicide layer is a conformal layer that covers the first epitaxial contact layer and the at least one second epitaxial contact layer.

14. The contact of the nanosheet structure of claim 11, wherein the two or more nanosheets are formed of silicon germanium doped with boron.

15. The contact of the nanosheet structure of claim 11, wherein the first epitaxial contact layer and the at least one second epitaxial contact layer have a higher germanium content than the source-drain material.

16. The contact of the nanosheet structure of claim 11, wherein the first epitaxial contact layer and the at least one second epitaxial contact layer have a higher boron content than the source-drain material.

17. The contact of the nanosheet structure of claim 11, wherein an uppermost surface of the source-drain forms a V-shape in the source-drain material at a (111) crystal plane of the source-drain material or wherein an uppermost surface of the source-drain forms a U-shape in the source-drain material.

18. The contact of the nanosheet structure of claim 17, wherein the V-shape has an angle of approximately 65 degrees to approximately 80 degrees.

19. A non-transitory, computer readable medium having instructions stored thereon that, when executed, cause a method for forming a contact for a nanosheet structure to be performed, the method comprising:
removing a source-drain material to form an exposed portion of a nanosheet material of at least one nanosheet;
forming epitaxial contact layers on the source-drain material and the exposed portion of the nanosheet material;
forming a silicide contact layer on at least the epitaxial contact layers; and
forming a contact with a metal material on the silicide contact layer.

20. The non-transitory, computer readable medium of claim 19, wherein the exposed portion of the nanosheet material comprises an entire end of the at least one nanosheet, wherein the exposed portion of the nanosheet material comprises an entire end of the at least one nanosheet and at least a portion of another nanosheet, or wherein the exposed portion of the nanosheet material comprises an entire end of one of the at least one nanosheet and an entire end of another one of the at least one nanosheet.
